(19) United States
(12) Patent Application Publication
(10) Pub. No.: US 2017/0025292 A1
(43) Pub. Date: Jan. 26, 2017

(54) LITHOGRAPHY APPARATUS, AND ARTICLE MANUFACTURING METHOD

(71) Applicant: CANON KABUSHIKI KAISHA, Tokyo (JP)

(72) Inventors: Masashi Kotoku, Yokohama-shi (JP); Kuniyasu Haginiwa, Yokohama-shi (JP)

(21) Appl. No.: 15/302,349

(22) PCT Filed: Feb. 27, 2015
(86) PCT No.: PCT/JP2015/001060

§ 371 Date: Oct. 6, 2016

(30) Foreign Application Priority Data
Apr. 15, 2014 (JP) 2014-083392

(51) Int. Cl. H01L 21/67

(52) U.S. Cl. CPC H01L 21/67276; H01L 21/67225

(57) ABSTRACT

Provided is a lithography apparatus that performs a patterning on a substrate. The lithography apparatus includes a processor configured to perform processing of assigning, to each of a plurality of substrates sequentially carried in from a first external apparatus, order information indicating an carrying-in order of the plurality of substrates; a plurality of units configured to respectively perform patternings of the plurality of substrates in parallel; and a transmitting device configured to transmit, to a second external apparatus, the order information corresponding to a substrate, of the plurality of substrates, carried out after being patterned thereon by one of the plurality of units.

### TECHNICAL FIELD

The present invention relates to a lithography apparatus, and an article manufacturing method.

### BACKGROUND ART

Conventionally, a lithography apparatus such as an exposure apparatus may be used in connection (inline connection) with a resist coating and developing apparatus (coater/developer). In this case, lithography processing (patterning) is performed in sequence to substrates sequentially carried in from the resist coater/developer. The substrate of which the processing has been performed is carried-out to the resist coater/developer with the carrying-in order being held. If the lithography apparatus does not carry out a substrate to the resist coater/developer because the predetermined processing cannot be performed for the substrate (which is also referred to as “the lost of a substrate”), the lithography apparatus notifies the resist coater/developer of the fact. As described above, even if the conventional lithography apparatus does not carry out a part of substrates, the conventional lithography carries out the carried-in substrate to the resist coater/developer without changing the order of the carried-in substrate. Conventionally, one resist coater/developer is in inline connection with one lithography apparatus. Thus, the resist coater/developer can perform processing for a substrate as long as the lithography apparatus includes a device configured to transmit information relating to switching between lots of substrates and a device configured to receive information relating to the lost of a substrate and it is ensured that there is no difference between the carrying-in order and the carrying-out order of the substrates.

Here, Patent Literature 1 discloses a substrate processing apparatus that includes a plurality of processing units provided therein, processes a plurality of substrates in parallel, and carries out a substrate to the downstream side in accordance with the carrying-in order regardless of the time at which the processing for the substrates is completed.

### CITATION LIST

### Patent Literature

Patent Literature 1: Japanese Patent No. 3938409

However, it may be disadvantageous for the cluster-type lithography apparatus constituted by a plurality of lithography units to carry out a substrate to an external apparatus in the carrying-in order. Here, the external apparatus is, for example, an apparatus that performs at least one of either preprocessing or postprocessing. In order to carry out a substrate to an external apparatus in the carrying-in order, the substrate of which the processing has been completed may need to be parked instead of being carried out immediately because a time required for processing one substrate may vary for each of a plurality of lithography units. In the cluster-type lithography apparatus, a plurality of lithography units may process in parallel substrates in plural lots of which the processing content (original, recipe, or the like) is different from each other. In this case, a time required for processing one substrate may also vary for each unit.

On the other hand, there is a request to reduce a time taken from lithography processing to development processing as much as possible or there is a request to hold a time taken from lithography processing to development processing constant as much as possible depending on the type of resist employed. In order to meet such requests, it may be advantageous for the lithography apparatus to reduce an unnecessary waiting time for a substrate and to convey a substrate immediately to a developer. In the cluster-type lithography apparatus, a difference in processing time between individual lithography units readily occurs. Thus, if an attempt is made to carry out the carried-in substrate without changing the order thereof, it becomes difficult to meet the above requests.

### SUMMARY OF INVENTION

The present invention provides, for example, a lithography apparatus which is advantageous in carrying-out of substrates, on each of which patterning has been performed, in an order different from an order of carrying-in of the substrates.

In order to overcome the above circumstances, a lithography apparatus that performs a patterning on a substrate is provided that includes a processor configured to perform processing of assigning, to each of a plurality of substrates sequentially carried in from a first external apparatus, order information indicating an carrying-in order of the plurality of substrates; a plurality of units configured to respectively perform patternings of the plurality of substrates in parallel; and a transmitting device configured to transmit, to a second external apparatus, the order information corresponding to a substrate, of the plurality of substrates, carried out after being patterned thereon by one of the plurality of units.

Further features of the present invention will become apparent from the following description of exemplary embodiments with reference to the attached drawings.

### BRIEF DESCRIPTION OF DRAWINGS

FIG. 1 is a block diagram illustrating a configuration of an apparatus to which the lithography apparatus according to the present embodiment is applicable.

FIG. 2 is a diagram illustrating a configuration of a processing unit of the lithography unit in the present embodiment.

FIG. 3 is a flow diagram illustrating the flow of processing according to the present embodiment.

### DESCRIPTION OF EMBODIMENTS

Hereinafter, preferred embodiments of the present invention will be described in detail with reference to the drawings.

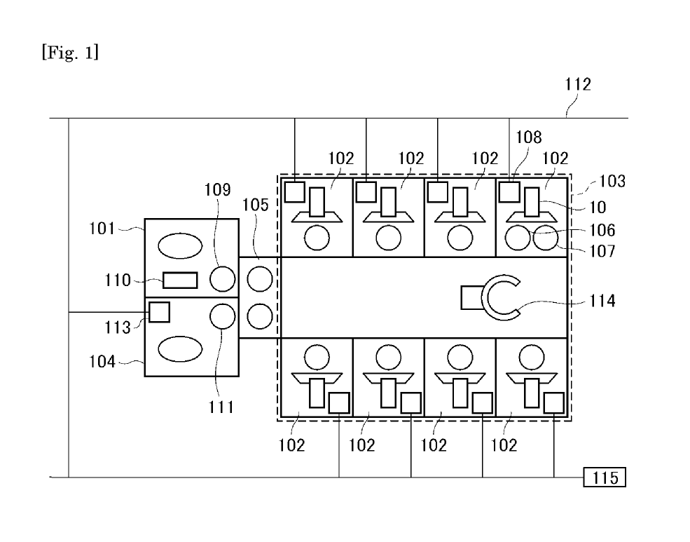

Firstly, a description will be given by taking a specific example of an apparatus to which the lithography apparatus according to an embodiment of the present embodiment is applicable. FIG. 1 is a block diagram illustrating a configuration of an apparatus to which the lithography apparatus according to an embodiment of the present embodiment is applied. The apparatus includes a resist coater 101 (preprocessing apparatus, first external apparatus), a cluster-type lithography apparatus 103 consisting of a plurality of units 102 (units), a developer 104 (postprocessing apparatus, second external apparatus), and a relay station 105 that relays among the resist coater 101, the developer 104, and the lithography apparatus 103. As viewed from the lithography apparatus 103, the resist coater 101 is an external apparatus that performs preprocessing of the lithography processing for a substrate and the developer 104 is an external apparatus that performs postprocessing of the lithography processing for a substrate. The lithography apparatus 103 includes a substrate conveyance (carrying) mechanism 114 that conveys a substrate between the relay station 105 and the unit 102. The lithography apparatus 103 also includes a cluster controller 115 (processor) that is an information processing apparatus for controlling the lithography units and monitoring the state thereof. When a plurality of units 112 performs patterning of a plurality of substrates in parallel, the cluster controller 115 can establish cooperation relationship and share information.

The resist coater 101 is an apparatus that performs a series of preprocessing for carrying in a substrate into a lithography apparatus, such as coating a photosensitive material on a substrate as preprocessing. The resist coater 101 has a substrate carrying-out unit 109 that passes a substrate to the relay station 105 to carry out the substrate to the lithography apparatus 103, and a substrate carrying-out order recording unit 110 that records the carrying-out order of substrates. The relay station 105 that relays a substrate, which has been carried out from the substrate carrying-out unit 109 of the resist coater 101, to the lithography apparatus 103 is provided between the lithography apparatus 103 and the resist coater 101. A substrate is carried in from the relay station 105 into a substrate carrying-in unit 106 of any one of the units 102 by the substrate conveyance mechanism 114.

The developer 104 is an apparatus that performs development processing, baking processing, or the like to a substrate as the postprocessing of the lithography processing and has a substrate carrying-in unit 111 and a substrate carrying-out information receiving unit 113. The substrate carrying-in unit 111 carries a substrate, which has been carried out from a substrate carrying-out unit 107 of any one of the units 102 provided in the lithography apparatus 103 through the relay of the relay station 105 using the substrate conveyance mechanism 114, to the developer 104. The substrate carrying-out information receiving unit 113 receives order information indicating the carrying-out order of the substrate, which has been transmitted with use of a communication network 112, from the unit 102.

The unit 102 is a unit that performs patterning of a substrate, which may be embodied as, for example, an exposure apparatus, a drawing apparatus, or an imprint apparatus. The exposure apparatus forms a (latent image) pattern onto a substrate (onto a resist) using, for example, (extreme) ultra-violet light. The drawing apparatus forms a (latent image) pattern onto a substrate (onto a resist) using, for example, charged particle beams (electron beams or the like). The imprint apparatus forms a pattern onto a substrate by molding an imprint material coated thereon with use of a mold. As shown in FIG. 1, the unit 102 has a substrate carrying-in unit 106, a substrate carrying-out unit 107, and an order information transmitting device 108 (transmitting device). The substrate carrying-in unit 106 receives a substrate, which has been carried by the substrate conveyance mechanism 114 through the relay of the relay station 105, from the resist coater 101. The substrate carrying-out unit 107 passes a substrate subjected to exposure or drawing by the unit 102 to the substrate conveyance mechanism 114 to carry out the substrate to the developer 104. The transmitting device 108 transmits order information, which has been obtained upon carrying-in of the substrate via the communication network 112 by aligning it to the carried-out substrate, to the developer 104 (second external apparatus). The unit 102 also has a processing unit 10 that performs pattern formation. A specific configuration of the processing unit 10 will be described below.

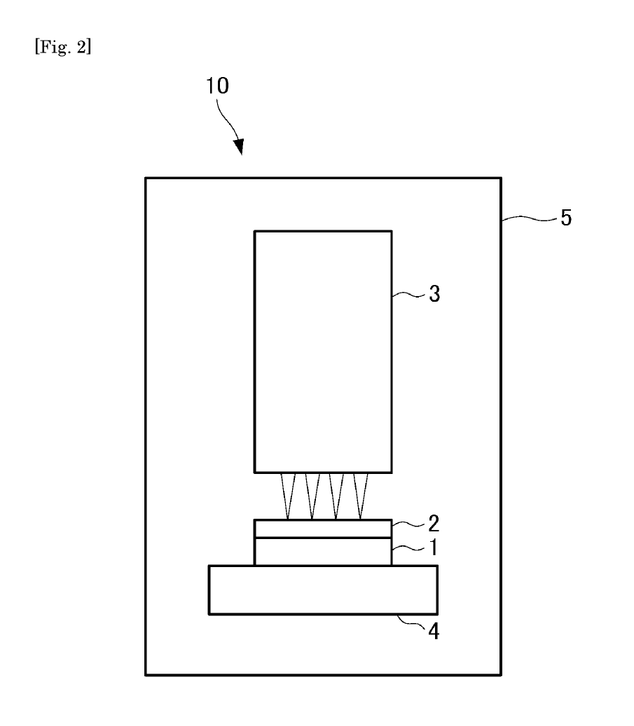

FIG. 2 is a diagram illustrating a configuration of the processing unit 10 included in the unit 102 as described above. Here, a drawing apparatus using electron beams is employed as the lithography unit. Note that electron beams may also be other charged particle beams such as ion beams. The processing unit 10 of the unit 102 includes a vacuum chamber 5, and an electron optical system 3 and a driving apparatus 4 both accommodated in the vacuum chamber 5, and performs drawing on a substrate 2 in vacuum using electron beams. A stage (holding unit) 1 holds the substrate 2.

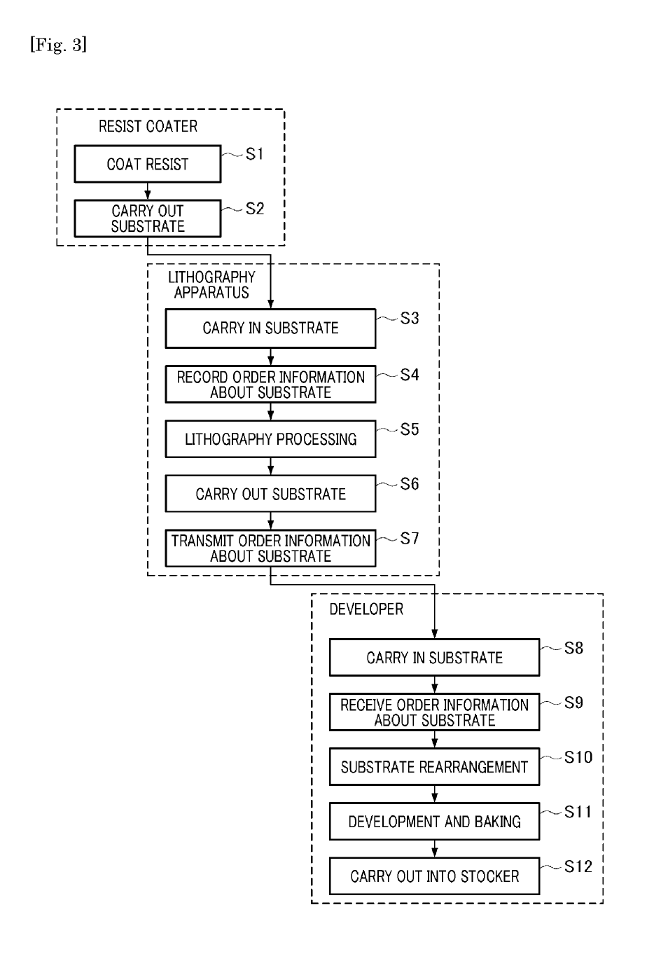

Next, a description will be given of the flow of processing according to the present embodiment. FIG. 3 is a flow diagram illustrating the flow of processing according to the present embodiment. Firstly, the resist coater 101 coats a resist onto a substrate (step S1), and then carries out the substrate to the lithography apparatus 103 to perform lithography processing (step S2). In general, the resist coater 101 performs resist coating onto a plurality of substrates under the same conditions and manages information indicating the fact that a resist is coated onto which substrate under which conditions. Next, the substrates sequentially carried in from the resist coater 101 are assigned and carried to any one of the units 102 through the relay of the relay station 105. Although it is contemplated that the assigning method may be accomplished in a number of ways, the assigning method is performed by, for example, the cluster controller 115 that manages the state of the lithography apparatus 103. The cluster controller 115 determines the load states of the units 102 and then assigns the substrates to the respective units 102 so as to increase the total throughput thereof. Next, the unit 102 receives a substrate (step S3), and the cluster controller 115 (processor) records order information (carrying-in order) which enables to identify the nth number of the substrate carried out by the resist coater 101 (first external apparatus) (step S4). As the method for generating order information, for example, the relay station 105 generates order information and assigns it to a substrate, and simultaneously gives the order information to the lithography unit to which the substrate is carried. If no order information is generated by the relay station 105, the front-back relationship between a substrate carried in into one unit 102 and another substrate carried in into another unit 102 is unknown. Thus, for example, each unit 102 records a time at which a substrate has been carried-in thereinto in order to identify the order of the substrates sequentially carried-in into the cluster-type lithography apparatus 103. Furthermore, a time standardized by taking into consideration of a different carrying time from a resist coater 101 is calculated for each unit 102, and the time is defined as order information indicating the carrying order of a substrate. When the cluster controller 115 (processor) records order information (step S4), the unit 102 aligns the substrate to perform lithography processing such as exposure, drawing by electron beams, or the like (step S5). Then, the substrate is placed on the substrate carrying-out unit 107, and the substrate conveyance mechanism 114 carries the substrate from the substrate carrying-out unit 107 to the relay station 105 (step S6). At the same time, the transmitting device 108 serving as the transmitting device gives order information indicating the order of the substrate, which has been recorded upon carrying-in thereof, to the relay station 105 (step S7). Here, in contrast to the conventional carrying-out of the substrate, the carrying-out of the substrate of which the processing has been completed by each individual unit 102 is not suspended due to incompletion of the processing of the substrate previously carried-in into another unit 102. Each individual unit 102 carries out the substrate of which the processing has been completed. The substrate is carried-in from the relay station 105 to the substrate carrying-in unit 111 of the developer 104 (step S8). The developer 104 receives order information about the carried-in substrate from the relay station 105 (step S9). A substrate stands by if a precedent substrate has not been carried-in, and the order of the substrate is rearranged if a precedent substrate is carried-in (step S10). The processing such as development, baking, and the like is performed (step S11), and the resulting substrates are stored in a stocker (step S12). Note that the order rearrangement of substrates in step S10 may also be performed after development and baking processing, i.e., after step S12.

Note that, in steps S7 and S9, order information may be transmitted/received by adding lot information representing a unit of exposure processing for a substrate to the order information. The processing for assigning lot information designating a lot corresponding to each of a plurality of substrates to each of the plurality of substrates is performed by the cluster controller 115 serving as the processor. Since a mixture of substrates in different lots may be processed by the cluster-type lithography apparatus 103, the developer 104 may not determine the processing content including the rearrangement of the order of each substrate by using only order information. Thus, the transmitting device 108 transmits the lot information (e.g., a unique lot name and a serial number for each lot) corresponding to the order information to the developer 104 and provides information required for determining the processing content for the developer 104. While the developer 104 performs transmission/reception of order information via the relay station 105 in steps S7 and S9, order information may also be transmitted/received directly to/from the unit 102 via the communication network 112. Furthermore, if an information processing apparatus for sharing and managing information is provided between the lithography apparatus and both the resist coater 101 and the developer 104, substrate order information may also be transmitted/received via the information processing apparatus in steps S7 and S9. More specifically, order information may also be transmitted to an information processing apparatus for lithography management, and the developer 104 serving as the postprocessing apparatus may be managed by the order information.

While, in the present embodiment, a description has been given by taking an example in which the resist coater 101 and the developer 104 are provided as independent apparatuses, the present invention is not limited thereto but the lithography apparatus of the present invention is also applicable to a coater/developer in which the resist coater 101 is integrated with the developer 104. In such a case, the problem can be resolved as long as how the order of a substrate has been rearranged is found upon return of the substrate carried-out toward the lithography apparatus 103. The resist coater 101 and the developer 104 can freely adjust the processing content depending on the type of substrate and rearrange the order of substrates. For example, the processing continues if the order of substrates having the same lot name representing a unit of exposure processing is just rearranged, but it may be determined to rearrange the order of substrates if the order is rearranged across different lots.

While, in the present embodiment, a description has been given of the case where a drawing apparatus using electron beams is employed as a lithography unit, a resist coater is employed as a preprocessing apparatus, and a developer is employed as a postprocessing apparatus, the present invention is not limited thereto. For example, in the case of a lithography apparatus in which an imprint apparatus is employed as a lithography unit, a resist coater may be employed as a preprocessing apparatus and an etching apparatus may be employed as a postprocessing apparatus.

While, in the present embodiment, a description has been given of the case where the relay station 105 generates order information, the cluster controller 115 is employed as a processor that performs processing for assigning order information to each substrate, and an order information transmitting device is employed as a transmitting device, the present invention is not limited thereto. For example, the substrate conveyance mechanism 114 may also generate order information and manage it until carrying-out the substrate. In this case, the substrate conveyance mechanism 114 may serve as both a processor and a transmitting device (or at least a part thereof). The substrate conveyance mechanism 114 may also generate order information to transfer it to the unit 102.

As described above, according to the present embodiment, the nth number of the substrate, which has been processed by each lithography unit in the cluster-type lithography apparatus, carried-out from an external apparatus for performing preprocessing can be determined by the external apparatus upon receiving it. Thus, each lithography unit can carry out the substrate, of which the patterning has been performed, in the order different from the carrying-in order without caring of a time taken for processing a substrate by another lithography unit and the carrying-out of the resulting substrate. Thus, a request to reduce a time taken from lithography processing to development processing may be met, resulting in an improvement in productivity.

(Article Manufacturing Method)

An article manufacturing method according to an embodiment of the present invention is preferred in manufacturing an article such as a micro device such as a semiconductor device or the like, an element or the like having a microstructure, or the like. The article manufacturing method may include a step of performing patterning (e.g., latent image pattern) of an object (e.g., substrate on which a photosensitive material is coated) using the aforementioned lithography apparatus; and a step of processing (e.g., step of developing) the object of which the latent image pattern has been performed in the previous step. Furthermore, the article manufacturing method may include other known steps (oxidizing, film forming, vapor depositing, doping, flattening, etching, resist peeling, dicing, bonding, packaging, and the like). The device manufacturing method of this embodiment has an advantage, as compared with a conventional device manufacturing method, in at least one of performance, quality, productivity and production cost of a device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-083392 filed on Apr. 15, 2014, which is hereby incorporated by reference herein in its entirety.

1. A lithography apparatus that performs a patterning on a substrate, the apparatus comprising:
a processor configured to perform processing of assigning, to each of a plurality of substrates sequentially carried in from a first external apparatus, order information indicating an carrying-in order of the plurality of substrates;
a plurality of units configured to respectively perform patternings of the plurality of substrates in parallel; and
a transmitting device configured to transmit, to a second external apparatus, the order information corresponding to a substrate, of the plurality of substrates, carried out after being patterned thereon by one of the plurality of units.

2. The lithography apparatus according to claim 1, wherein the processor is configured to perform processing of further assigning, to each of the plurality of substrates, lot information designating a lot corresponding thereto, and the transmitting device is configured to further transmit the lot information corresponding to the order information to the second external apparatus.

3. The lithography apparatus according to claim 1, wherein the first external apparatus is a preprocessing apparatus that performs preprocessing of the patterning.

4. The lithography apparatus according to claim 1, wherein the second external apparatus is a postprocessing apparatus that performs postprocessing of the patterning.

5. The lithography apparatus according to claim 1, wherein the first external apparatus and the second external apparatus are included in a single machine.

6. The lithography apparatus according to claim 5, wherein the first external apparatus and the second external apparatus are included in a coating and developing machine.

7. The lithography apparatus according to claim 1, wherein the second external apparatus is an information processing apparatus configured to manage lithography.

8. The lithography apparatus according to claim 7, wherein the information processing apparatus is configured to manage a postprocessing apparatus configured to perform postprocessing of the patterning.

9. The lithography apparatus according to claim 1, wherein each of the plurality of units is configured to perform a patterning on a substrate using at least one of light, a charged particle and a mold.

10. A method of manufacturing an article, the method comprising steps of:
performing patterning on a substrate using a lithography apparatus, and
processing the substrate, on which the patterning has been performed, to manufacture the article,
wherein the lithography apparatus comprises:
a processor configured to perform processing of assigning, to each of a plurality of substrates sequentially carried in from a first external apparatus, order information indicating an carrying-in order of the plurality of substrates;
a plurality of units configured to respectively perform patternings of the plurality of substrates in parallel; and
a transmitting device configured to transmit, to a second external apparatus, the order information corresponding to a substrate, of the plurality of substrates, carried out after being patterned thereon by one of the plurality of units.
